(19) United States
(12) Patent Application Publication
(10) Pub. No.: US 2014/0240007 A1
(43) Pub. Date: Aug. 28, 2014

(54) Drive Circuit For Power Transistor

(71) Applicant: Control Techniques Limited, Newtown (GB)

(72) Inventor: Richard Samuel Gibson, Shrewsbury (GB)

(73) Assignee: Control Techniques Limited, Newtown (GB)

(21) Appl. No.: 14/192,022

(22) Filed: Feb. 27, 2014

(30) Foreign Application Priority Data
Feb. 28, 2013 (GB) 1303585.2

(51) Int. Cl. H03K 17/00

(52) U.S. Cl. CPC H03K 17/00
USPC 327/109

(57) ABSTRACT

A turn-on drive circuit for a power transistor comprising a first circuit comprising a resistor and capacitor in parallel and a second circuit comprising a resistor, the second circuit being in series in the drive path with the first circuit. A turn-off drive circuit for a power transistor comprising a first circuit comprising a first resistor and a second resistor in series in the drive path of the power resistor and a second circuit comprising a capacitor in parallel with one of the resistors of the first circuit.

### CROSS-REFERENCE TO RELATED APPLICATION

This application claims the benefit and priority of Great Britain Patent Application No. 1303585.2 filed Feb. 28, 2013. The entire disclosure of the above application is incorporated herein by reference.

### FIELD

This application relates to improved drive circuits for power transistors and in particular to methods of limiting the dissipation of energy by a power transistor (for example an insulated gate bipolar transistor (IGBT)) during turn-on and turn-off, in particular by controlling transient voltages and currents when the power transistor is switched on or when the power transistor is switched off.

### BACKGROUND

A power transistor, such as an IGBT or a power MOSFET, is a device primarily used as an electronic power switch. Power transistors such as IGBTs are highly efficient and fast switching. The transient behaviour of a power transistor when switched on or switched off is critical to its operating performance. During switch on and switch off of the power transistor, transient voltages contribute significantly to the electromagnetic interference (EMI) signature of the device and cause energy to be dissipated as heat, which negatively affects the efficiency of the power transistor.

The energy loss during switch on of a power transistor is referred to herein as Eon. The energy loss during switch off of a power transistor is referred to herein as Eoff.

Power circuits including power transistors require well designed drive circuits to minimise losses while efficiently driving a power transistor. For instance, European patent application No. EP 2306647 describes a drive circuit for a switching device in which a gate resistor is provided for adjusting speeds of turn-on and turn-off of a semiconductor switching device and a capacitor is connected in parallel with the resistor.

However the arrangement as shown in EP 2306647 has the disadvantage that the turn-on- and turn-off time may be too fast leading to uncontrolled transient performance.

### BRIEF DESCRIPTION OF THE DRAWINGS

The proposed circuit will now be described further, by way of example only, with reference to the accompanying drawings, in which:

FIG. 1 shows an embodiment of a turn-on drive circuit for a semi-conductor switching device;

FIGS. 2a and 2b show an example of the switching characteristics of the drive circuit shown in FIG. 1 compared with an alternative drive circuit;

FIG. 3 shows an embodiment of a turn-off drive circuit for a semi-conductor switching element;

FIG. 4 shows a switching characteristic of the turn-off drive circuit of FIG. 3; and

FIG. 5 shows a switching characteristic of the turn-off drive circuit of FIG. 3.

### DESCRIPTION

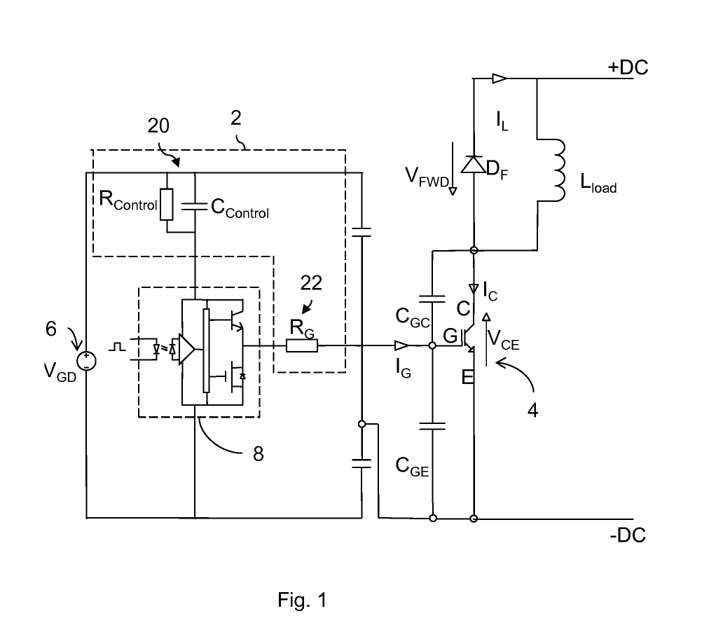

Turning to FIG. 1, there is shown a turn-on drive circuit 2 for a semiconductor switching device 4. The input of the turn-on circuit 2 is for connection to a power supply 6 and the output of the turn-on circuit 2 is for connection to the drive of the semiconductor switching device 4. The drive current to the semiconductor switching device 4 may be controlled by a microprocessor-controlled switch 8. The turn-on signal from a microprocessor will, in most cases, require a current amplifier to supply charge to the input of the semiconductor switching device 4 and turn on the device. This can be achieved with a microprocessor-controlled switch 8 such as a power MOSFET or a gate drive optocoupler as illustrated in FIG. 1. The power circuit has supply rails +DC and −DC.

In the example shown in FIG. 1, the semiconductor switching device 4 (also known as a power transistor) is an Insulated Gate Bipolar Transistor (IGBT) with a gate electrode G for receiving a drive signal, an emitter electrode E and a collector electrode C for driving a load L_{load}. The description will be made with reference to the power transistor being an IGBT. However the drive circuit may have application with other power transistors, e.g. power MOSFETs.

The turn-on drive circuit 2 comprises a first circuit 20 comprising a resistor R_{control} in parallel with a capacitor C_{control} and a second circuit 22 comprising a resistor R_{G}. The first and second circuits 20, 22 are in series with each other in the drive path of the semiconductor switching device 4. FIG. 1 shows the microprocessor-controlled switch 8 located between the first circuit 20 and the second circuit 22. It will be appreciated that the microprocessor-controlled switch 8 may alternatively be located before the first circuit 20 as viewed in FIG. 1.

The input G of the IGBT can be represented as a variable capacitor whose value is dependent on the operating voltage and transient stage i.e. when current flows into the gate terminal, the gate emitter voltage (V_{GE}) increases. When switching on the IGBT into an existing inductor current I_{L}, the collector current Ic begins to rise when V_{GE} increases beyond the threshold of the device. The rate at which the collector current I_{c} rises is related to the rate of change of voltage at the gate terminal by the device transconductance. When the collector current I_{c} reaches the inductor load current I_{L}, the freewheel diode D_{F} can begin to turn off and then block the voltage across the load L_{load}. The increase in blocking voltage is reflected to the IGBT as a reduction in the collector emitter voltage (V_{CE}). The IGBT internal capacitance between gate and collector (C_{GC}) must be supplied with gate current to allow the voltage to fall. Typically the gate current and hence switching speed may be controlled using a gate resistor (R_{G}). The value of resistor R_{G} is increased to find an acceptable EMI performance for the product by limiting the dV_{CE}/dt. This results in an increase in the turn-on energy loss Eon.

The rapid change in V_{CE} can have a significant impact on electromagnetic interference (EMI) such as conducted and radiated emissions. The described circuit presents a method which allows a small gate resistor R_{G} to be used to minimise losses associated with the current rise, while offering control of dV_{ce}/dt over all or part of the voltage fall time by the C_{control}/R_{control} circuit.

As shown in FIG. 1, a capacitor C_{control} is used to store a charge ready to supply to the IGBT with only the minimum gate resistor value R_{G} being used (sufficient to dampen unwanted oscillations). The charge stored by C_{control} is not sufficient to completely turn on the IGBT but is chosen to allow the gate voltage V_{GE} to rise to a level which will allow the full load current to be carried by the IGBT.

A resistor R_{Control} inserted in parallel to the capacitor C_{Control} is selected to restrict the flow of charge into the IGBT during the fall of the collector voltage V_{CE} so reducing the fall rate. It is possible to reduce the dV_{CE}/dt over the entire voltage range or a latter part of the fall time. Current flowing through R_{Control} is required to completely turn on the IGBT ensuring low conduction losses and to also recharge C_{Control} in preparation for the next switching cycle.

The value of R_{G} controls the ramp-up rate of the collector current I_{C} which significantly affects the switching losses Eon at turn-on. The steeper the rise in I_{C}, the lower the switching losses. The values of R_{control} and C_{control} control the V_{CE} drop after turn on.

In the case of the turn-on circuit 2, the turn-on circuit 2 comprises a resistor R_{Control} in parallel with the capacitor C_{Control} and a resistor R_{G} in series with the resistor R_{Control} and the capacitor C_{Control}. This means that initially current will flow through the uncharged capacitor C_{Control} (which acts initially like a short circuit) and through the resistor R_{G}. Subsequently, as the capacitor C_{Control} becomes fully charged, the current flows through both the resistor R_{Control} and the resistor R_{G}. The value of the resistor R_{G} in series with the capacitor C_{Control} is less than the value of the resistor R_{Control} in parallel with the capacitor. For example typical values which may be used are 4.7 Ohms for R_{G} and 10 Ohms for R_{Control} although the actual values of R_{G} and R_{Control} will depend on the specific power transistor and other components used. The value of R_{G} controls the ramp-up rate of the collector current I_{c} which significantly affects the switching losses Eon at turn-on. The value of R_{Control} controls the flow of charge into the IGBT during the fall of the collector voltage V_{CE} so reducing the fall rate.

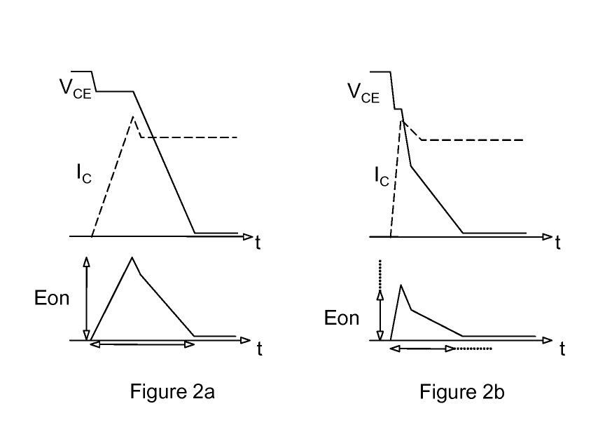

The turn-on switching loss (Eon) can be determined by multiplying the instantaneous voltages and currents to find the instantaneous power then integrating over the switching time. In an effort to minimize the switching loss, it is desirable to reduce the gate resistance allowing charge to flow into the gate at an increased rate hence increasing the rate of current rise. This also has the effect of supplying more charge to discharge C_{GC} rapidly hence increasing dV_{CE}/dt. FIG. 2a illustrates V_{CE} and I_{C} in the top graph and Eon in the lower graph for a drive circuit comprising the second circuit R_{G} but without the first circuit 20. FIG. 2b illustrates V_{GE} and I_{C} in the top graph and Eon in the lower graph for a drive circuit comprising the second circuit R_{G} and the first circuit 20.

As can be seen in FIG. 2b, the addition of the first circuit 20 to the turn-on drive circuit 2 results in the V_{CE} drop off occurring more rapidly than without this circuit (the results of which are shown in FIG. 2a). The turn-on switching loss Eon is therefore reduced in both peak magnitude and duration.

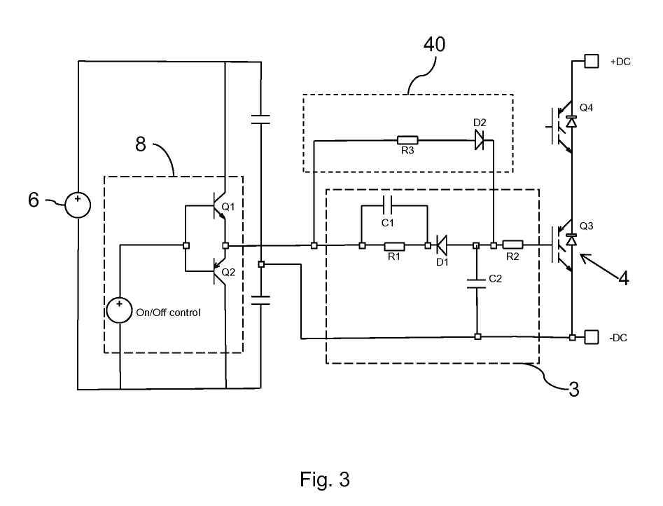

FIG. 3 shows an embodiment of a turn-off drive circuit 3. Components that are the same in FIG. 3 as in FIG. 1 are denoted by the same reference numeral. The turn-off drive circuit 3 comprises a network comprising a capacitor C1 in parallel with a first resistor R1, a second resistor R2 in series in the drive path of the semiconductor switching device 4 and a second capacitor C2. The turn-off drive circuit 3 for a power transistor therefore comprises a first circuit comprising a first resistor R1 and a second resistor R2 in series in the drive path of the power transistor and a second circuit comprising a capacitor C1 in parallel with one of the resistors R1, R2 of the first circuit. The turn-off drive circuit 3 controls the ramp up rate of the output voltage (Vice) of the power transistor at the instant of turn-off demand from the microprocessor by rapidly discharging the IGBT internal capacitance. The values of R1 and R2 are chosen so that R1 is greater than R2 and are used to limit the dV_{ce}/dt at the point where the current begins to ramp down to complete the turn off procedure.

The turn-off process of an IGBT takes a finite duration of time during which energy is dissipated as heat loss. The proposed turn-off drive circuit should reduce the turn-off switching time and hence reduce the turn-off losses without increasing the radiated emissions.

This improved IGBT turn-off control can be achieved with the use of a single passive capacitor (C1 in FIG. 3), located in parallel to the large portion of turn-off resistance R1 and with the optional capacitor C2 to give an increase in precision.

In FIG. 3, a possible turn-on drive circuit 40 is shown comprising resistor R3 and diode D2 to control the gate current flow during turn on. However an alternative turn-on drive circuit may be used, such as that shown in FIG. 1.

During turn off, the drive output of the optocoupler 8 is pulled negative. Current will flow from the IGBT gate terminal G through R2, D1, R1 and C1. Another current will also flow from C2, through D1, C1 and R1.

At the instance of switching, a large current will flow through R2, D1 and C1 rapidly discharging the gate capacitance to a voltage determined by the midpoint between C1 and C2, causing Vice to rise rapidly shortening the power loss time.

In the case of the turn-off circuit 3, the turn-off circuit 3 comprises a resistor R1 in parallel with the capacitor C1 and a resistor R2 in series with the resistor R1 and capacitor C1. This means that initially current will flow through the resistor R2 and the uncharged capacitor C1 (which acts initially like a short circuit). Subsequently, as the capacitor C1 becomes fully charged, the current flows through both the resistor R2 and the resistor R1. The value of the resistor R2 in series with the capacitor C1 is less than the value of the resistor R1 in parallel with the capacitor C1. For example typical values which may be used are 4.7 Ohms for R2 and 10 Ohms for R1 although the actual values of R2 and R1 will depend on the specific power transistor and other components used. The value of R2 controls the ramp-down rate of the emitter current I_{E} which significantly affects the switching losses Eoff at turn-off. The value of R1 controls the flow of charge out of the IGBT during the rise of the collector voltage V_{CE} so reducing the rise rate.

C1 is selected to ensure that the initial positive current flow through the capacitor will have reduced to zero or turned negative before the Vce voltage has risen to +DC (the positive supply rail). This forces the gate current I_{G} to reduce by flowing through the series combination of R2 and R1 (a higher impedance). This reduction in gate current maintains a low value of dIc/dt minimizing the voltage overshoot due to parasitic inductance and will not increase the radiated emissions.

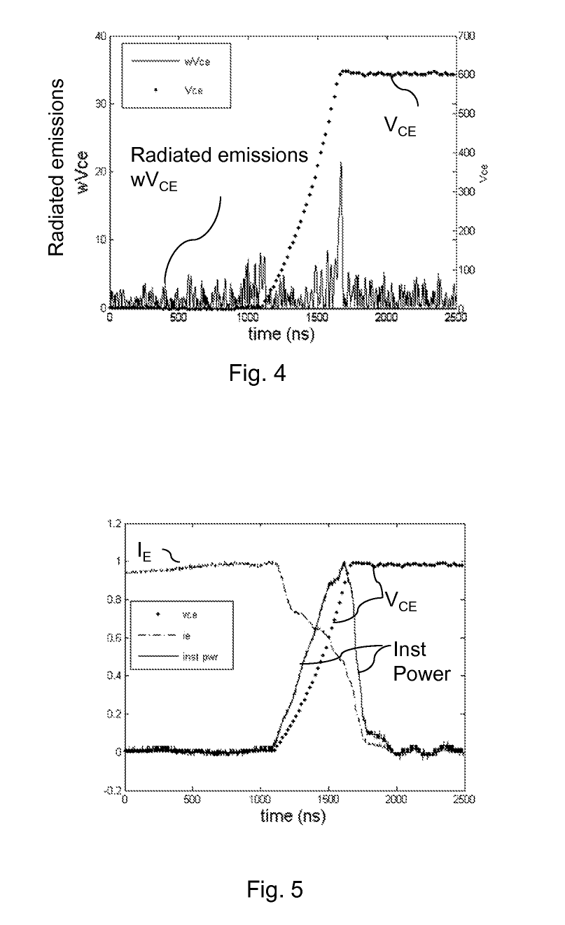

The peak source of the radiated emissions has been identified using a wavelet transform as shown in FIG. 4 (wVce—radiated emissions). This occurs at the peak voltage overshoot of Vce (as shown in FIG. 4).

The turn-off drive circuit 3 as shown in FIG. 3 should rapidly take the power transistor 4 out of saturation.

FIG. 5 shows an example of normalised Vce and Ic. The instantaneous power dissipation (Inst Power) is found by multiplying Vce and Ic. It can be seen from FIG. 5 that the majority of the turn-off energy (Inst Power) is dissipated before the peak voltage overshoot has been reached (shown at around 1650 ns).

The values of the capacitors and resistors discussed herein are in practice determined empirically for each circuit to be used.

Drive circuits as discussed herein allow radio frequency (RF) emissions to be better controlled and so assist in optimising RF noise versus switching time and losses and enable control of voltage overshoots and surges in the output voltage of a power transistor. The drive circuits are passive circuits with passive devices and do not require feedback of the output voltage or current of the power transistor for control.

1. A turn-on drive circuit for a power transistor comprising a first circuit comprising a resistor and capacitor in parallel and a second circuit comprising a resistor, the second circuit being in series in the drive path with the first circuit.

2. A turn-on drive circuit for a power transistor as claimed in claim 1 wherein the value of the resistor in the first circuit controls the ramp rate of the output voltage of the power transistor.

3. A turn-on drive circuit for a power transistor as claimed in claim 1 wherein the second circuit controls the output current of the power transistor.

4. A turn-on circuit as claim in claim 1 when used in a circuit with an insulated gate bipolar transistor “IGBT”.

5. A turn-off drive circuit for a power transistor comprising a first circuit comprising a first resistor and a second resistor in series in the drive path of the power transistor and a second circuit comprising a capacitor in parallel with one of the resistors of the first circuit.

6. A turn-off drive circuit for a power transistor as claimed in claim 5 wherein the first circuit controls the ramp up rate of the output voltage of the power transistor.

7. A turn-off drive circuit for a power transistor as claimed in claim 5 wherein the second circuit controls the drive voltage of the power transistor.

8. A turn-off drive circuit for a power transistor as claimed in claim 5 further comprising a capacitor arranged in a T-network with the first and second resistor.

9. A turn-off circuit as claim in claim 5 when used in a circuit with an insulated gate bipolar transistor “IGBT”.
